(19) United States
(12) Patent Application Publication
(10) Pub. No.: US 2024/0113854 A1
(43) Pub. Date: Apr. 4, 2024

(54) PHASE DIFFERENCE CONTROL CIRCUIT

(71) Applicants: SKAIChips Co., Ltd., Suwon-si (KR); Research & Business Foundation SUNGKYUNKWAN UNIVERSITY, Suwon-si (KR)

(72) Inventors: Kang Yoon LEE, Seoul (KR); Hyung Ki HUH, Seoul (KR); Jong Wan JO, Suwon-si (KR); Ho Won KIM, Suwon-si (KR)

(73) Assignees: SKAIChips Co., Ltd., Suwon-si (KR); Research & Business Foundation SUNGKYUNKWAN UNIVERSITY, Suwon-si (KR)

(21) Appl. No.: 18/111,889

(22) Filed: Feb. 21, 2023

(30) Foreign Application Priority Data
Sep. 30, 2022 (KR) 10-2022-0125491

(51) Int. Cl. H04L 7/033; H04W 56/00

(52) U.S. Cl. CPC H04L 7/0331; H04W 56/0035

(57) ABSTRACT

Internal phase shifting is achieved by adding a feedback divider to a feedback loop of a phase locked loop circuit configured to determine a transmission frequency of a wireless transmission terminal and adding a phase adjustment current to a loop current. Since the phase adjustment current is applied to an adder circuit, a phase difference is maintained even when the feedback loop is in a stable state, and accordingly, an output of the feedback divider maintains the phase difference with a reference frequency as intended by the phase adjustment current applied to the adder circuit.

This application claims priority from Korean Patent Application No. 10-2022-0125491, filed on Sep. 30, 2022, in the Korean Intellectual Property Office, the disclosure of which is incorporated herein by reference in its entirety.

### BACKGROUND

### 1. Field

A technology related to a circuit which generates a clock having a selected phase difference with respect to a reference clock is disclosed.

### 2. Description of Related Art

A radio frequency (RF) phase shifter technology which controls a phase difference for beamforming transmission is known. An analog phase shift circuit using a transmission line having a length corresponding to a phase difference to be adjusted has large loss and has a limitation in terms of frequency band or phase control. Further, for example, in a field such as wireless power transmission technology that transmits power to a selected target using beamforming technology, precision of phase shifting is required, but it is difficult to satisfy this condition by such analog-based technology.

### SUMMARY

The present disclosure is directed to realizing a phase shifting function by modifying a phase locked loop among existing circuits without separately adding a radio frequency (RF) phase shifter.

Further, the present disclosure is directed to increasing the resolution of phase shift adjustment.

Further, the present disclosure is directed to decreasing errors in phase shifting adjustment.

According to one aspect of the present disclosure, internal phase shifting is achieved by adding a feedback divider to a feedback loop of a phase locked loop circuit configured to determine a transmission frequency of a wireless transmission terminal and adding a phase adjustment current to a loop current. Since the phase adjustment current is applied to an adder circuit, a phase difference is maintained even when the feedback loop is in a stable state, and accordingly, an output of the phase locked loop circuit maintains the phase difference with a reference frequency as intended by the phase adjustment current applied to the adder circuit.

According to an additional aspect, phase comparison signals between internal signals of the phase locked loop circuit and signals obtained by dividing or delaying the internal signals may be accumulated to generate the phase adjustment current.

According to an additional aspect, one arbitrarily selected among a plurality of current sources may be connected to an internal capacitor so that an output current of a charge pump becomes constant on average.

### BRIEF DESCRIPTION OF THE DRAWINGS

FIG. 1 is a block diagram illustrating a configuration of a phase shift circuit according to one embodiment.

FIG. 2 is an exemplary timing diagram between internal signals of the circuit in FIG. 1.

FIG. 3 is a block diagram illustrating a configuration of a phase shift circuit according to another embodiment.

FIG. 4 illustrates one embodiment of a charge/discharge circuit of a charge pump.

FIG. 5 is an exemplary timing diagram between internal signals of the circuit in FIG. 3.

FIG. 6 is a block diagram illustrating a configuration of a phase shift circuit according to still another embodiment.

FIG. 7 is an exemplary timing diagram between internal signals of the circuit in FIG. 6.

FIG. 8 is a block diagram illustrating a configuration of a phase shift circuit according to yet another embodiment.

FIG. 9 is a block diagram illustrating a configuration of a phase shift circuit according to yet another embodiment.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The above-described and additional aspects are embodied through the embodiments described with reference to the accompanying drawings. It is understood that the components of each embodiment may be variously combined within one embodiment or with components of another embodiment unless otherwise mentioned or contradicted by each other. The terms used in the specification and the claims should be interpreted as meanings and concepts consistent with the invention or the proposed technical spirit based on the principle that the inventor can appropriately define the concept of a term to describe the invention thereof in the best way. Hereinafter, preferable embodiments of the present disclosure will be described in detail with reference to the accompanying drawings.

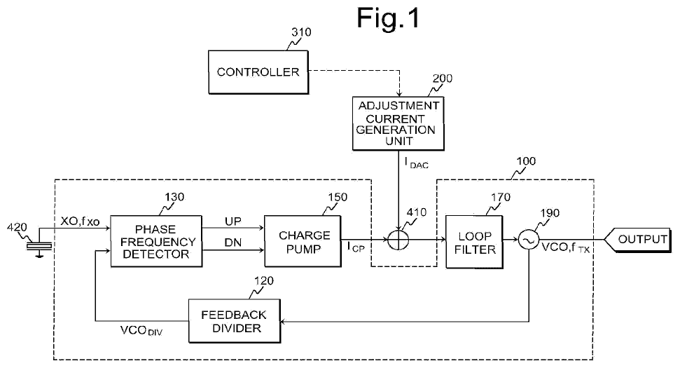

### Description of Embodiment in FIG. 1—Description of Invention of Claim 1

According to one aspect of the present disclosure, internal phase shifting is configured by adding a phase adjustment current to a loop current of a phase locked loop circuit of a wireless transmission terminal having a multi-array antenna. FIG. 1 is a block diagram illustrating a configuration of a phase shift circuit according to one embodiment to which this aspect is applied. As shown in the drawing, the phase shift circuit according to one embodiment includes a phase locked loop circuit 100 and an adder circuit 410. The phase locked loop circuit 100 may be one of various types of generally known phase locked loop circuits. According to one aspect, the phase-locked loop circuit includes a feedback divider 120 in a feedback loop.

The adder circuit 410 adds the phase adjustment current to the loop current of the phase locked loop circuit 100. The adder circuit 410 may be implemented as an analog adder circuit when the phase locked loop circuit 100 is implemented as an analog circuit. As another example, when the phase locked loop circuit 100 is implemented as a digital circuit, the adder circuit 410 may be implemented as a digital adder circuit.

An output frequency of the phase locked loop circuit 100 fluctuates as much as the phase adjustment current added by the adder circuit. A phase frequency detector 130 maintains a constant phase difference between two inputs in a stable state due to the phase adjustment current although the phase difference between the two inputs should be originally 0 through a feedback divider 120. According to one aspect, since the phase adjustment current is applied to the adder circuit 410, this phase difference is maintained even when the feedback loop is in a stable state, and accordingly, an output of a voltage-controlled oscillator 190 or the feedback divider 120 has a phase difference with respect to a reference frequency as intended by the phase adjustment current applied to the adder circuit. The output of the voltage-controlled oscillator 190 may be transmitted to an antenna as a transmission signal of a wireless power transmission circuit through a power amplifier.

### Description of Embodiment in FIG. 1—Description of Invention of Claims 2, 3, and 4

In the illustrated embodiment, the phase locked loop circuit may include the phase frequency detector (PFD) 130, a charge pump 150, a loop filter 170, and the voltage-controlled oscillator 190. The phase frequency detector 130 compares a phase difference between a reference clock output from a reference clock generation unit 420 and a feedback signal fed back from the voltage-controlled oscillator 190 to output a comparison signal. In the illustrated embodiment, the phase frequency detector 130 detects a phase and a frequency of each of the reference clock output from the reference clock generation unit 420 and the feedback signal fed back from the voltage-controlled oscillator 190 to activate an up output (UP) when the phase difference is positive and activate a down output (DN) when the phase difference is negative.

The charge pump 150 outputs a loop current by performing charging and discharging according to the comparison signal output from the phase frequency detector 130. The charge pump 150 increases an output current by performing charging when the up input (UP) is activated, and decreases the output current by performing discharging when the down input (DN) is activated. The loop filter 170 filters the output of the charge pump 150 to generate a control voltage of the voltage-controlled oscillator 190. The voltage-controlled oscillator 190 is a known circuit which outputs a square wave having a frequency proportional to an input control voltage. Since detailed configurations and operations of these individual functional circuits are known in the field of phase locked loop circuits, detailed descriptions thereof will be omitted.

In one embodiment, the phase shift circuit may further include a controller 310. In the illustrated embodiment, the controller 310 determines an amount of phase shift and outputs a control signal according to the amount of phase shift. The controller 310 may have a form of an operation unit which outputs different resistance values as a user adjusts the controller 310 using a knob. As another example, the controller 310 may be implemented as a microprocessor which determines and outputs a phase adjustment current value to be transmitted to a target reception antenna in response to an external instruction. As still another example, the controller 310 may be implemented by some of the program instructions in an external controller. In a phase shift circuit having a fixed phase shift value, the controller 310 is not necessary.

An adjustment current generation unit 200 generates and outputs a phase shift value added to the adder circuit 410, that is, the phase adjustment current herein. In the illustrated embodiment, the adjustment current generation unit 200 is implemented as a digital-to-analog converter which converts a digital current value determined according to a phase adjustment amount and output from the controller 310 to an analog current value and outputs the analog current value. However, the present disclosure is not limited thereto, and the adjustment current generation unit 200 may be implemented as various circuits which output a digital control value of the controller 310, which may be output with various scales or offsets, as an analog current value capable of adjusting an offset of the phase locked loop circuit 100 of a specific structure. Further, when the phase locked loop circuit 100 is implemented as a digital circuit, the adjustment current generation unit 200 may simply be a digital circuit configured to output a digital value which represents a current value added according to an instruction of the controller 310. For example, the adjustment current generation unit 200 may be implemented as a memory having an input instruction value as an address input and a phase adjustment current value as a data output. As another example, in a phase shift circuit having a fixed phase shift value, the adjustment current generation unit 200 may be a constant current source which outputs a current having a predetermined magnitude.

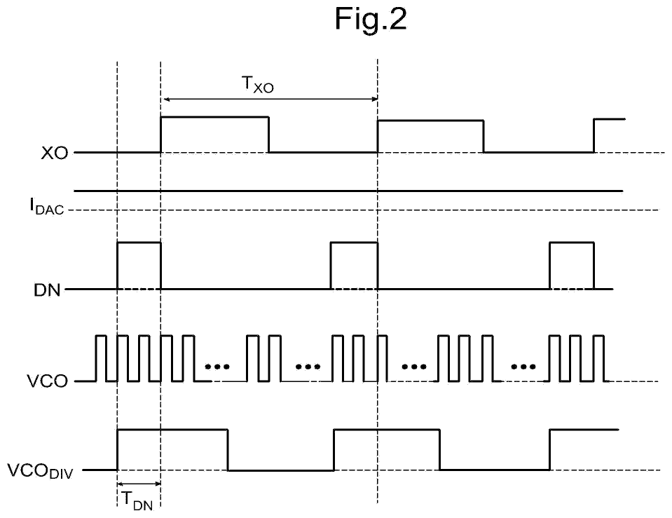

### Description in FIG. 2—Operation of Circuit of Embodiment in FIG. 1

FIG. 2 is an exemplary timing diagram between internal signals of the circuit in FIG. 1. As shown in the drawing, as a phase adjustment current I_{DAC} is added to the output of the charge pump 150, an output VCO of the voltage-controlled oscillator 190 or an output VCO_{DIV} of the feedback divider 120, which divides the output, has a phase difference T_{DN} with an output XO of the reference clock generation unit 420. For ease of understanding, in the drawing, the phase difference T_{DN} is exaggeratedly shown to cover a plurality of clocks, but actually, the phase difference T_{DN} is more generally implemented as a phase shift within one clock range of the output VCO of the voltage-controlled oscillator 190. In this case, the output VCO of the voltage-controlled oscillator 190 and the output VCO_{DIV} of the feedback divider 120, which divides the output, have the same phase difference as the output XO of the reference clock generation unit 420.

Unlike a common phase locked loop circuit, an output of the phase frequency detector 130 represents a phase difference caused by the phase adjustment current. In the illustrated timing example, a DN signal is output during a section in which a phase difference between the output XO of the reference clock generation unit 420 and the output VCO_{DIV} of the feedback divider 120 is detected. The UP signal is activated in the case of a positive phase difference, and the DN signal is activated in the case of a negative phase difference.

In the phase locked loop circuit 100 in FIG. 1, since the total amount of charges introduced into the loop filter in a locked state should be 0, the following equation is satisfied. Here, a current I_{CP} is a current value while the DN signal is activated.

T_{XO}×I_{DAC}=T_{DN}×I_{CP} (1)

Accordingly, when a division ratio of the feedback divider 120 is M, a phase shift of T_{XO}×I_{DAC}/I_{CP} (corresponding to M×I_{DAC}/I_{CP}×360 degrees) occurs in a time domain in the phase shift circuit according to one embodiment of the present disclosure compared to a general phase locked loop circuit. The resolution of the phase shift of this circuit may be expressed as follows.

I_{DAC,RESOLUTION}=I_{CP}/M/360 (2)

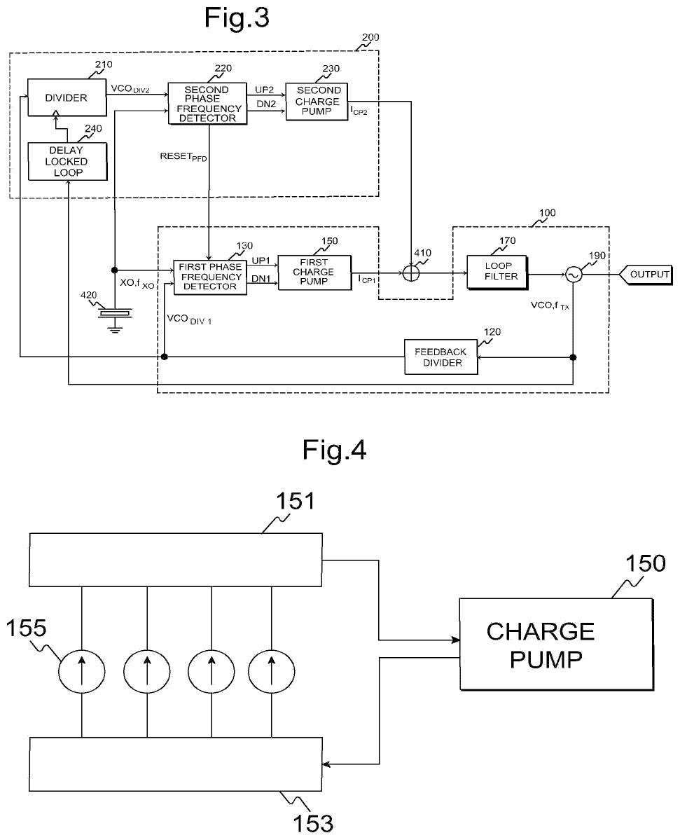

### Description of Embodiment in FIG. 3—Description of Invention of Claim 1

According to one aspect of the present disclosure, internal phase shifting is configured by adding a phase adjustment current to a loop current of a phase locked loop circuit of a wireless transmission terminal having a multi-array antenna. FIG. 3 is a block diagram illustrating a configuration of a phase shift circuit according to another embodiment to which this aspect is applied. Configurations similar to the embodiment of FIG. 1 are referred to by the same reference numerals. As shown in the drawing, the phase shift circuit according to another embodiment includes a phase locked loop circuit 100 and an adder circuit 410. The phase locked loop circuit 100 may be one of various types of generally known phase locked loop circuits. According to one aspect, the phase-locked loop circuit includes a feedback divider 120 in a feedback loop.

The adder circuit 410 adds the phase adjustment current to the loop current of the phase locked loop circuit 100. The adder circuit 410 may be implemented as an analog adder circuit when the phase locked loop circuit 100 is implemented as an analog circuit. As another example when the phase locked loop circuit 100 is implemented as a digital circuit, the adder circuit 410 may be implemented as a digital adder circuit.

Since an output frequency of the phase locked loop circuit 100 fluctuates as much as the phase adjustment current added by the adder circuit, and is fed back, a phase shift occurs. According to one aspect, since the phase adjustment current is applied to the adder circuit 410, this phase difference is maintained even when the feedback loop is in a stable state, and accordingly, an output of a voltage-controlled oscillator 190 has a phase difference with a reference frequency as intended by the phase adjustment current applied to the adder circuit.

### Description of Embodiment in FIG. 3—Description of Invention of Claims 2 and 5

In the illustrated embodiment, the phase locked loop circuit may include a first phase frequency detector (PFD) 130, a first charge pump 150, a loop filter 170, and the voltage-controlled oscillator 190. The first phase frequency detector 130 compares a phase difference between a reference clock output from a reference clock generation unit 420 and a feedback signal fed back from the voltage-controlled oscillator 190 to output a comparison signal. In the illustrated embodiment, the phase frequency detector 130 activates an up output (UP1) when the phase difference is positive and activates a down output (DN) when the phase difference is negative.

The first charge pump 150 performs charging and discharging according to an output of the first phase frequency detector 130. The first charge pump 150 increases an output current by performing charging when the up input (UP1) is activated, and decreases the output current by performing discharging when the down input (DN1) is activated. The loop filter 170 filters the output of the first charge pump 150 to generate a control voltage of the voltage-controlled oscillator 190. The voltage-controlled oscillator 190 is a known circuit which outputs a square wave having a frequency proportional to an input control voltage. Since detailed configurations and operations of these individual functional circuits are known in the field of phase locked loop circuits, detailed descriptions thereof will be omitted.

### Description of Embodiment in FIG. 3—Description of Invention of Claims 6, 7, 8, and 9

An adjustment current generation unit 200 generates and outputs a phase shift value added to the adder circuit 410, that is, the phase adjustment current herein. According to an additional aspect, the phase adjustment current may be generated by accumulating phase comparison signals between internal signals of the phase locked loop circuit and signals acquired by dividing or delaying the internal signals. In the illustrated embodiment, the adjustment current generation unit 200 includes a delay locked loop 240, a divider 210, a second phase frequency detector 220, and a second charge pump 230.

The delay locked loop 240 is a known circuit which includes a plurality of delay taps connected in series and sequentially delays and outputs reference clock signals input from the outside. An output of the voltage-controlled oscillator 190 is delayed in the delay locked loop 240 and then supplied to the divider 210. The divider 210 receives and divides an output of the feedback divider 120, and then outputs the output in synchronization with the output of the voltage-controlled oscillator delayed by the delay locked loop 240.

The second phase frequency detector 220 compares a phase between a reference clock output from a reference clock generation unit 420 and an output of the divider 210 to output a second comparison signal. In the illustrated embodiment, the second phase frequency detector 220 activates an up output (UP2) when the phase difference is positive, and activates a down output (DN2) when the phase difference is negative. Here, the first phase frequency detector 130 is reset with a reset signal RESET_{PFD} output from the second phase frequency detector 220, and synchronized with the same reference clock XO.

The second charge pump 230 outputs a phase adjustment current as a phase adjustment signal by performing charging and discharging according to the second comparison signal that is an output of the second phase frequency detector 220. The second charge pump 230 increases an output current by performing charging when the up input (UP) is activated, and decreases the output current by performing discharging when the down input (DN) is activated.

Since the output of the divider 210 has a longer period than the output of the feedback divider 120, the output of the second phase frequency detector 220 may have a greater width than the output of the first phase frequency detector 130, and a phase adjustment current I_{CP2} may have a wider fluctuation width than a loop current I_{CP1} of the phase locked loop circuit 100. Since the delay locked loop 240 directly receives and delays the output of the voltage-controlled oscillator 190 without passing through the feedback divider 120, and thus synchronizes the output of the divider 210, the output of the second phase frequency detector 220 may be more precisely adjusted according to the configuration of the delay locked loop 240, which means that the resolution of the phase shift may be improved. From this description, it should be understood that the divider 210 and the delay locked loop 240 are independent components which do not need to be provided at the same time, and may be selectively combined.

In the embodiment shown in FIG. 1, matching circuits to make the degree of activation of the UP signal and the degree of activation of the DN signal the same to control the degree of phase adjustment in both directions is difficult because current sources in opposite directions should be matched. On the other hand, in the embodiment shown in FIG. 3, since only a ratio of the current I_{CP1} and the current I_{CP2} should be adjusted to control the degree of phase adjustment in both directions, controlling the degree of phase adjustment in both directions may be more easily achieved by matching the current sources in the same direction. For example, the degree of phase adjustment may be controlled in both directions by matching the DN signal of the first charge pump and the DN signal of the second charge pump. In this case, the UP signals do not require matching at all.

According to an additional aspect, one arbitrarily selected among a plurality of current sources may be connected to the charge pump so that the output current of the charge pump becomes constant on average. According to this aspect, the phase shift circuit according to one embodiment may include the plurality of current sources and a random charge/discharge switching unit. FIG. 4 illustrates one embodiment of a charge/discharge circuit of a charge pump to which this aspect is applied. Although the first charge pump 150 is shown and described as the shown charge/discharge circuit in FIG. 3, the same may be applied to the second charge pump 230, and preferably applied to both charge pumps at the same time.

As shown in the drawing, the charge/discharge circuit may include a plurality of current sources 155 and random charge/discharge switching units 151 and 153. The random charge/discharge switching units 151 and 153 connect one arbitrarily selected among the plurality of first current sources 155 to a charging input of the charge pump 150 according to the comparison signal output from the phase frequency detector. The random charge/discharge switching units 151 and 153 may include a random charge switching unit 151 and a random discharge switching unit 153. The random charge switching unit 151 connects one arbitrarily selected among the plurality of first current sources 155 to the charging input of the charge pump 150 when the comparison signal output from the phase frequency detector is the UP signal. The random discharge switching unit 153 connects one arbitrarily selected among the plurality of first current sources 155 to a discharging input of the charge pump 150 when the comparison signal output from the phase frequency detector is the DN signal. According to this structure, the output current of the charge pump is determined through a dynamic weight average method. The output of the charge pump is determined by one arbitrarily selected among a plurality of current sources connected in parallel without depending on one current source. Accordingly, stable locking can be achieved by reducing mismatches in the loop current of the phase locked loop circuit.

According to an additional aspect, the delay locked loop 240 may be a digital delay locked loop. The digital delay locked loop delays the output of the voltage-controlled oscillator according to a delay control word and supplies the output to a synchronization input of the divider 210. Korean Patent No. 744,069 filed on Dec. 27, 2005 discloses a delay locked loop circuit using digital and analog control. As disclosed therein, when the delay locked loop circuit is implemented as a semiconductor integrated circuit, stable operation regardless of process, voltage, and temperature (PVT) fluctuations may be secured. A delay due to a receiver difference may be automatically controlled during a beamforming operation or a beam scanning operation using this structure.

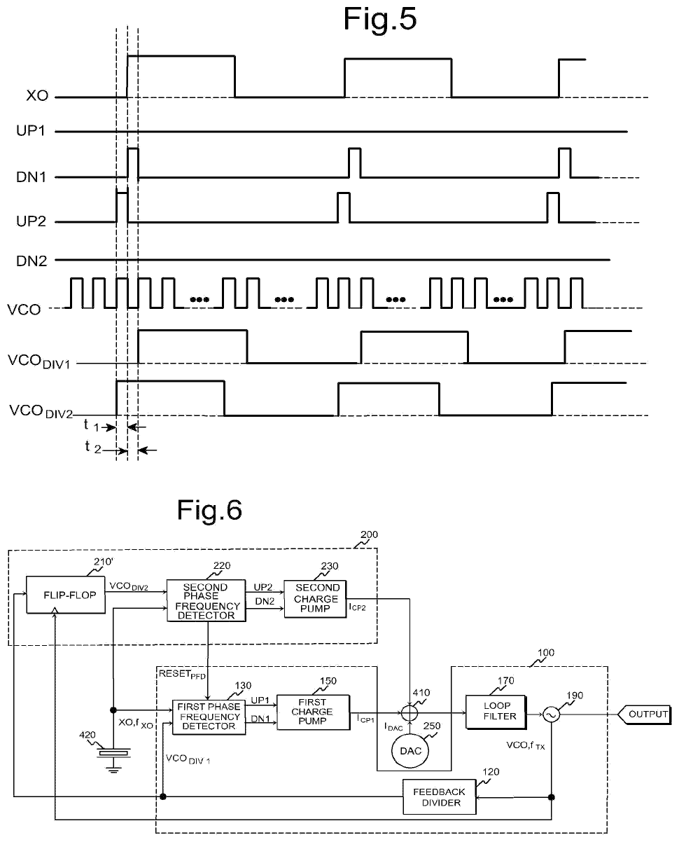

### Description in FIG. 5—Operation of Circuit of Embodiment in FIG. 3

FIG. 5 is an exemplary timing diagram between internal signals of the circuit in FIG. 3.

As shown in the drawing, as the phase adjustment current I_{CP2} is added to the output of the charge pump 150, the output VCO of the voltage-controlled oscillator 190 or the output VCO_{DIV1} of the feedback divider 120, which divides the output, has a phase difference t₂ with the output XO of the reference clock generation unit 420. Unlike a general phase locked loop circuit, the output of the phase frequency detector 130 represents the phase difference caused by the phase adjustment current. As shown in the exemplary drawing, the first phase frequency detector 130 outputs the comparison signal during a section in which a phase difference between the output XO of the reference clock generation unit 420 and the output VCO_{DIV1} of the feedback divider 120 is detected. The UP1 signal is activated when the phase difference is a positive phase difference, and the DN1 signal is activated when the phase difference is a negative phase difference.

In the phase locked loop circuit 100 in FIG. 3, since the total amount of charges introduced into the loop filter 170 in a locked state should be 0, the following equations are satisfied in the timing diagram in FIG. 5. Here, the currents I_{CP1} and I_{CP2} are current values while the DN1 and DN2 signals are activated, respectively.

T_{DN1}×I_{CP1}=T_{UP2}×I_{CP2}

T_{VCO}=T_{DN1}+T_{UP2}

I_{CP}=I_{CP1}+I_{CP2}

t₁:t₂=I_{CP2}:I_{CP1} (3)

Accordingly, when a division ratio of the feedback divider 120 is M, a phase shift of I_{CP2}/(I_{CP1}+I_{CP2})×360 degrees occurs in the phase shift circuit according to another embodiment of the present disclosure compared to a general phase locked loop circuit. The resolution of the phase shift of this circuit may be expressed as follows.

I_{CP,RESOLUTION}=I_{CP}/M/360 (4)

Accordingly, the resolution of the phase shift may be improved compared to the embodiment in FIG. 1.

### Description of Embodiment in FIG. 6—Description of Invention of Claim 10

FIG. 6 is a block diagram illustrating a configuration of a phase shift circuit according to still another embodiment. The illustrated embodiment differs from the embodiment shown in FIG. 3 in that it further includes a digital-to-analog converter 250. The digital-to-analog converter 250 converts the control word output from the controller to an analog signal and supplies the analog signal as an additional phase adjustment signal to the adder circuit 410.

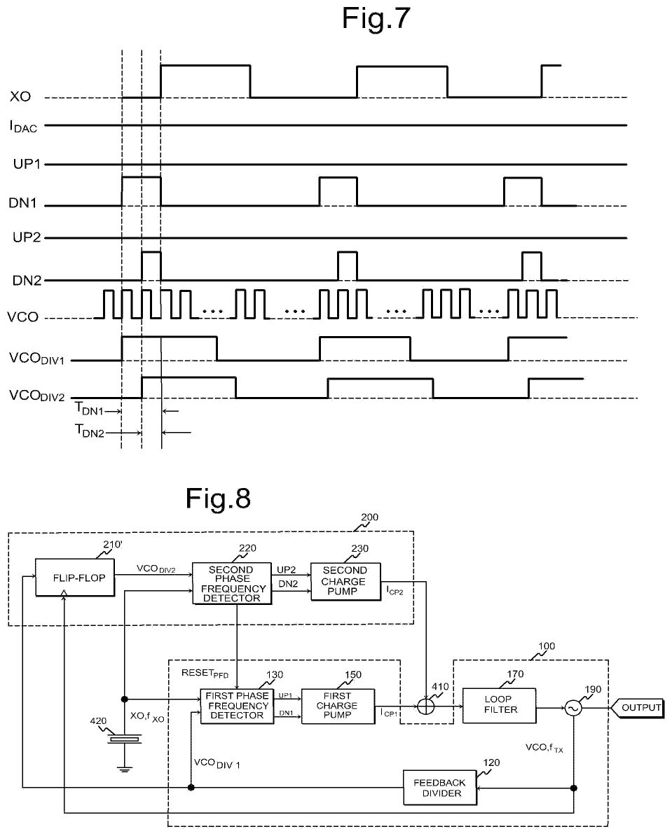

### Description in FIG. 7—Operation of Circuit of Embodiment in FIG. 6

FIG. 7 is an exemplary timing diagram between internal signals of the circuit in FIG. 6. As described above, in the phase locked loop circuit 100 in FIG. 6, since the total amount of charges introduced into the loop filter 170 in a locked state should be 0, the following equations are satisfied in the timing diagram in FIG. 7. Here, the currents I_{CP1} and I_{CP2} are current values while the DN1 and DN2 signals are activated, respectively.

T_{DN1}×I_{CP1}T_{UP2}×I_{CP2}=T_{XO}×I_{DAC}

T_{VCO}=T_{DN1}−T_{DN2}

I_{CP}=I_{CP1}+I_{CP2} (5)

Accordingly, when a division ratio of the feedback divider 120 is M, a phase shift of ((T_{XO}×I_{DAC})/(T_{VCO}×I_{CP})+I_{CP2}/lop)×360 degrees occurs in the phase shift circuit according to the illustrated embodiment compared to a general phase locked loop circuit. When (T_{XO}×I_{DAC})/(T_{VCO}×I_{CP}) is fixed as a constant, I_{CP,RESOLUTION}=I_{CP}/360 is necessary for acquiring a unit phase shift. This means that the same degree of phase shifting is achieved with a unit current M times greater and higher resolution is acquired than the above-described embodiments.

### Description of Embodiment in FIG. 8—Description of Invention of Claim 11

FIG. 8 is a block diagram illustrating a configuration of a phase shift circuit according to yet another embodiment. The embodiment in FIG. 8 is an embodiment in which the delay locked loop 240 has a delay amount of ‘0,’ that is, is removed from the embodiment in FIG. 3, and thus the output of the voltage-controlled oscillator 190 is directly supplied without a delay, and the divider 210 is implemented as a flip-flop 210′ having a division ratio of ‘1.’ In the illustrated embodiment, the flip-flop 210′ is a D-flip-flop. Accordingly, a detection signal output by the second phase frequency detector 220, which determines the phase adjustment signal I_{CP2}, is similar to a detection signal output by the first phase frequency detector 130, but may be clocked by the voltage-controlled oscillator 190 and may be adjusted with high resolution.

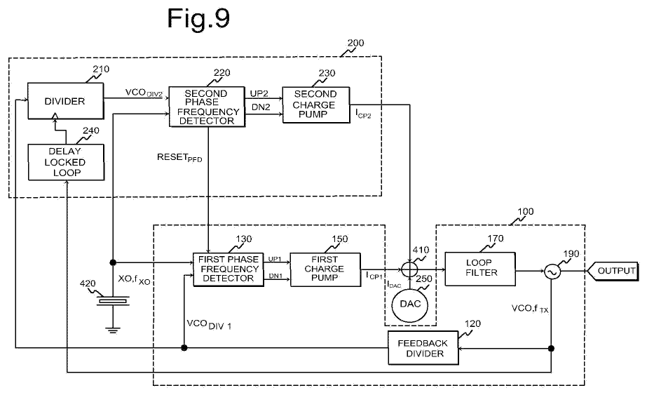

### Description of Embodiment in FIG. 9—Description of Invention of Claim 12

FIG. 9 is a block diagram illustrating a configuration of a phase shift circuit according to yet another embodiment. The embodiment in FIG. 9 differs from the embodiment shown in FIG. 8 in that it further includes a digital-to-analog converter 250. The digital-to-analog converter 250 converts the control word output from the controller to an analog signal and supplies the analog signal as an additional phase adjustment signal to the adder circuit 410. The embodiment in FIG. 9 is an embodiment in which the delay locked loop 240 has a delay amount of ‘0,’ that is, is removed from the embodiment in FIG. 6, and thus the output of the voltage-controlled oscillator 190 is directly supplied without a delay, and the divider 210 is implemented as a flip-flop 210′ having a division ratio of ‘1.’ In the illustrated embodiment, the flip-flop 210′ is a D-flip-flop.

According to the present disclosure, a phase shift function is realized by modifying a phase locked loop among existing circuits without adding a separate radio frequency (RF) phase shifter. Beamforming, which reduces signal mismatches in a reception antenna, is stable, and improves space efficiency, is achieved by avoiding path loss due to the addition of a separate phase shifter, and precisely controlling phase shifting without an error.

In the above, although the present disclosure has been described with reference to the accompanying drawings, the present disclosure is not limited thereto, and should be understood to encompass various modifications which may be clearly derived by those skilled in the art. For example, the phase locked loop circuit may be implemented as an all-digital phase locked loop (all-digital PLL) circuit. The claims are intended to encompass these modifications.

What is claimed is:

1. A phase shift circuit comprising:
a phase locked loop circuit including a feedback divider in a feedback loop; and
an adder circuit configured to add a phase adjustment current to a loop current of the phase locked loop circuit.

2. The phase shift circuit of claim 1, wherein the phase locked loop circuit further includes:
a first phase frequency detector (PFD) configured to compare a phase between a reference clock and an input frequency to output a first comparison signal;
a first charge pump configured to perform charging and discharging according to the first comparison signal to output a loop current;
a loop filter configured to filter the loop current; and
a voltage-controlled oscillator configured to oscillate according to a loop filter output voltage,
wherein the feedback divider is configured to divide an output frequency of the voltage-controlled oscillator to supply the divided output frequency as an input frequency to the first PFD.

3. The phase shift circuit of claim 1, further comprising an adjustment current generation unit configured to output a phase adjustment current signal from a control word output from a controller.

4. The phase shift circuit of claim 3, wherein the adjustment current generation unit is a digital-to-analog converter configured to convert the control word output from the controller to an analog signal and output the analog signal as the phase adjustment current signal.

5. The phase shift circuit of claim 2, further comprising an adjustment current generation unit configured to generate a phase adjustment current signal and output the phase adjustment current signal to the adder circuit.

6. The phase shift circuit of claim 5, wherein the adjustment current generation unit includes:
a divider configured to receive an output of the feedback divider and synchronize the output with an output of the voltage-controlled oscillator to output the synchronized output;
a second phase frequency detector (PFD) configured to compare a phase between the reference clock and the output of the divider to output a second comparison signal; and
a second charge pump configured to perform charging and discharging according to the second comparison signal to output a phase adjustment current.

7. The phase shift circuit of claim 6, further comprising:
a first random charge/discharge switching unit configured to connect a plurality of first current sources and one arbitrarily selected among the plurality of first current sources according to the first comparison signal to a charge/discharge input of the first charge pump; and
a second random charge/discharge switching unit configured to connect a plurality of second current sources and one arbitrarily selected among the plurality of second current sources according to the second comparison signal to a charge/discharge input of the second charge pump.

8. The phase shift circuit of claim 6, further comprising a delay locked loop configured to delay the output of the voltage-controlled oscillator to supply the output as a synchronization input of the divider.

9. The phase shift circuit of claim 8, wherein the delay locked loop is a digital delay locked loop configured to delay the output of the voltage-controlled oscillator according to a delay control word to supply the output as the synchronization input of the divider.

10. The phase shift circuit of claim 7, further comprising a digital-to-analog converter configured to convert a control word output from a controller to an analog signal, and supply the analog signal as an additional phase adjustment signal to the adder circuit.

11. The phase shift circuit of claim 5, wherein the adjustment current generation unit includes:
a flip-flop configured to receive an output of the feedback divider and synchronize the output with an output of the voltage-controlled oscillator to output the synchronized output;
a second phase frequency detector (PFD) configured to compare a phase between the reference clock and the output of the flip-flop to output a second comparison signal; and
a second charge pump configured to perform charging and discharging according to the second comparison signal to output a loop current.

12. The phase shift circuit of claim 11, further comprising a digital-to-analog converter configured to convert a control word output from a controller to an analog signal, and supply the analog signal as an additional phase adjustment current signal to the adder circuit.

13. A wireless transmission device comprising:
the phase shift circuit according to claim 1;
a modulator configured to modulate input data with a signal phase shifted in the phase shift circuit;
a power amplifier configured to amplify an output of the modulator; and
an antenna configured to wirelessly transmit an output of the power amplifier.
